(19) United States
(12) Patent Application Publication
(10) Pub. No.: US 2004/0062129 A1
(43) Pub. Date: Apr. 1, 2004

(54) Method and apparatus for enhancing the efficiency of dynamic RAM

(75) Inventors: Ronald P. Novick, Orange, CT (US); Andrew J. Eckhardt, Shelton, CT (US)

Correspondence Address: David P. Gordon, Esq., 65 Woods End Road, Stamford, CT, 06905, US

(73) Assignee: TranSwitch Corporation

(21) Appl. No.: 10/259,013

(22) Filed: Sep. 27, 2002

(51) Int. Cl. G11C 5/00

(52) U.S. Cl. 365/230.03; 365/238.5

(57) ABSTRACT

Methods for enhancing the efficiency of SDRAM include dividing all of the data blocks into at least two parts and storing each part in a different bank of memory. Specifically, the first part of each data block is stored in the first bank of memory and subsequent parts are stored in other banks. Since every data block begins in one bank and ends in another bank, no memory bank is ever accessed twice consecutively. In this manner it is always possible to perform precharge and row activation for the next data access while finishing the present data access. The methods of the invention are illustrated in conjunction with the storage and retrieval of ATM cells.

### BACKGROUND OF THE INVENTION

1. Field of the Invention

The invention relates to dynamic random access memory devices. More particularly, the invention relates to a technique for enhancing the efficiency of synchronous dynamic random access memory (SDRAM). The invention is particularly applicable in telecommunications involving fixed length packets such as ATM (asynchronous transfer mode) cells or variable length packets.

2. State of the Art

Synchronous dynamic random access memory (SDRAM) is presently the most efficient random access memory available. As used herein, the term “efficient” means the speed at which information may be read from or written to the memory in comparison to the cost of the memory. SDRAM is efficient because it is relatievly inexpensive and all operations are synchronized to the same clock signal as the processor which is used to access the SDRAM. The timing coordination between memory, the microprocessor, and other support chips permits more efficient memory access and eliminates system wait states. Although SRAM allows faster access than SDRAM, it is more expensive.

SDRAM is organized in two or four banks and each bank is organized into a number of rows and columns. Organization in banks allows the “pipelining” of data access. Pipelined data access means that one bank can be transferring data while another is preparing to transfer data. SDRAM also utilizes programmable “burst” transfer. Burst transfer means that a number of sequential memory locations are accessed following a single read or write command.

Despite the many improvements over prior RAM devices, SDRAM is still subject to specific latency issues. For example, read and write access to an SDRAM device begins with the selection of a row (also referred to as a page) and a bank via input signals. Only one row (page) per bank can be “open” at one time. The process of opening a page (selecting a row) is referred to as “row activation”. The time latency consumed by row activation is referred to as tRCD and is measured in a number of clock cycles. A typical tRCD is two clock cycles. Thus, from the time the row activation signal is asserted, at least two clock cycles must elapse before data can be read or written. Row activation is followed by a read or write command which includes the column address of the first data word in the transfer. After the first data word is transferred, subsequent words are transferred every subsequent clock cycle (one word per cycle) until the “burst” is complete. The number of clock cycles (data words) in a burst is programmable. Before a different row can be accessed in the same bank, the currently selected row must be closed (precharged). The number of clock cycles consumed to complete the precharge command is referred to as tRP. A typical tRP is two clock cycles. Although SDRAM is the most efficient memory device currently available, consecutive data access is often delayed by tRP+tRCD, the time needed to close one row and open another. In addition to this latency there is always one clock cycle of overhead between a block read and a block write operation to avoid contention on the bidirectional SDRAM data bus. Moreover, when a block write is followed by a block read, CAS latency clock cycles are added to the overhead. CAS (column access strobe) latency is typically two or three clock cycles.

### SUMMARY OF THE INVENTION

It is therefore an object of the invention to provide methods and apparatus for enhancing the efficiency of SDRAM.

It is also an object of the invention to provide methods and apparatus for enhancing the efficiency of SDRAM when storing telecommunications packets.

In accord with these objects which will be discussed in detail below, the methods of the present invention include dividing all of the data packets into at least two parts and storing each part in a different bank of memory. Specifically, the first part of each data packet is stored in the first bank of memory and subsequent parts are stored in other banks. Since every data packet begins in one bank and ends in another bank, no memory bank is ever accessed twice consecutively. In this manner it is always possible to perform precharge and row activation for the next data access while finishing the present data access. According to the invention, if a block read is followed by a block read, or a block write is followed by a block write, no overhead is needed. If a block read is followed by a block write, only one clock cycle of overhead is needed to avoid contention on the bidirectional SDRAM data bus. If a block write is followed by a block read, only the CAS latency clock cycles are needed as overhead. The methods of the invention are illustrated in conjunction with the storage and retrieval of ATM cells. Accordingly, the division of cells into two parts is easily calculated. The methods of the invention can also be applied to the storage and retrieval of variable length packets. In this case, packets are divided into segments of burst size length until the end of packet is reached.

Additional objects and advantages of the invention will become apparent to those skilled in the art upon reference to the detailed description taken in conjunction with the provided figures.

### BRIEF DESCRIPTION OF THE DRAWINGS

FIG. 1 is a simplified flowchart illustrating the methods of the invention as applied to the storage and retrieval of ATM cells;

FIG. 2 is a simplified flowchart illustrating the methods of the invention as applied to the storage of variable length packets; and

FIG. 3 is a simplified block diagram illustrating an apparatus for performing the methods of the invention.

### BRIEF DESCRIPTION OF THE APPENDIX

The enclosed CD-ROM appendix is incorporated herein by reference. The CD-ROM is in ISO 9660 Macintosh® format and includes the following Adobe® Acrobat® files:

| List of files | Size (Bytes) | Date of Creation |
|---|---|---|
| DCB_FR_ed_2_5.pdf | 228,381 | Mar. 30, 2002 |

The file DCB_FR_ed_{—}2_{—}5.pdf is a document entitled “Aspen Express DRAM Controller Block (DCB) Requirements Specification” which illustrates in detail a presently preferred embodiment of the invention.

### DETAILED DESCRIPTION OF THE PREFERRED EMBODIMENTS

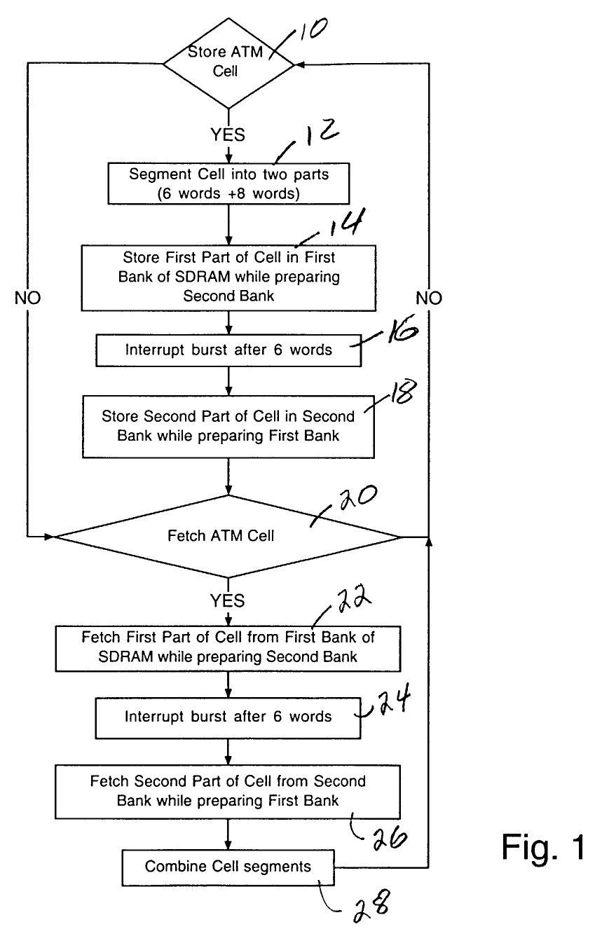

FIG. 1 illustrates an exemplary method according to the invention. The method illustrated in FIG. 1 assumes that the packets to be stored and fetched are all ATM cells (i.e. fixed length packets of fifty-three bytes). The method illustrated in FIG. 1 also assumes that the SDRAM has two banks and data is stored in 32-bit words. Thus, the number of words needed to store an ATM cell is fourteen. According to the invention, the ATM cell is stored in two parts, with part of the cell being stored in the first bank and the other part of the cell being stored in the second bank. Since the burst length is eight words, each ATM cell is stored in two segments; one being eight words, and the other being six words. Eight and six are chosen so that only one burst needs to be shortened. According to the presently preferred embodiment of the invention, the six word segment is stored in the first bank of the SDRAM. In this manner, the first burst can be interrupted after six clock cycles and total overhead can be shortened by two clock cycles.

Turning now to FIG. 1, if it is determined at 10 that an ATM cell is to be stored in SDRAM, the cell is segmented into two parts (a six word part and an eight word part) at 12. A first burst is started and the six word part is written into the first bank of RAM at 14 while the second bank is prepared. The preparation of the second bank may involve four clock cycles to precharge a row and activate a different row. In any event, the second bank will be ready when the first burst is interrupted after six words at 16. The second part of the cell is then stored at 18 during an eight word burst while the first bank is prepared for the next access. The preparation of the first bank for the next access will involve no more than four clock cycles to precharge a row and activate a different row if the next access is a block write (store) operation. If the next access is a block read (fetch) operation, additional CAS latency clock cycles will be required.

If it is determined at 20 that an ATM cell is to be read from the SDRAM, the first six words are read from the first bank at 22 while the second bank is prepared. The burst is interrupted after six cycles at 24 and the second part of the cell is read at 26 while the first bank is prepared for the next access. The two segments of the ATM cell are combined at 28.

As mentioned above, normal random read and write operations in an SDRAM require four clock cycles for precharge and row activation. In addition, when a read operation follows a write operation, up to three CAS latency clock cycles are required and when a write operation follows a read operation, one clock cycle is required to avoid contention on the SDRAM data bus. Thus, when SDRAM is randomly accessed in a conventional way, an average of 4-6 additional clock cycles will be required for each block access. By dividing each block access over two banks, the present invention guarantees that each block access will begin in a bank other than the bank where the last block access ended. Thus, no bank is accessed twice consecutively. In this way, bank access is always “pipelined”.

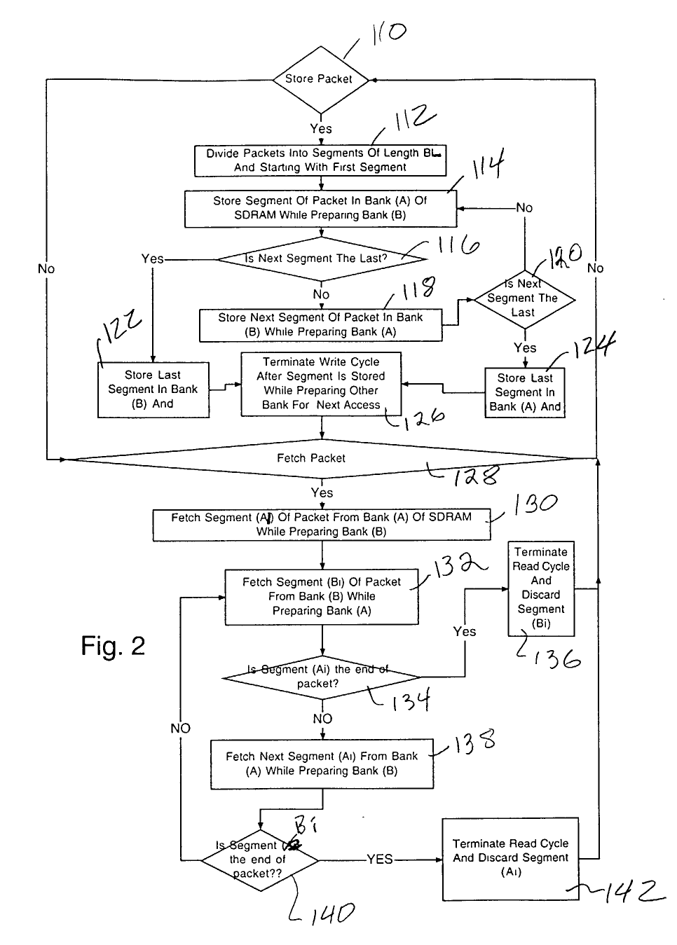

As mentioned above, the methods of the invention can also be used with variable length packets. FIG. 2 is a simplified high level flowchart illustrating how the methods of the invention are applied to variable length packets.

Starting at 110, if it is determined that a packet is to be stored, the packet is divided into a number of segments of length BL (burst length) at 112. All of the segments except for the last segment are the size of the burst length (BL). The size of the last segment is BS-BL. At 114, the first segment of the packet is stored in bank A of RAM while preparing bank B. The next segment is examined at 116 to determine whether it is the end of packet segment. If it is not, it is stored in bank B while preparing bank A at 118. The next segment is examined at 120 to determine whether it is the end of the packet. If it is not, it is stored in bank A while preparing bank B at 114. This process continues until it is determined at 116 or 120 that the next segment is the end of the packet. Then the last segment is stored in the appropriate bank at 122 or 124. The write cycle is terminated at 126.

If it is determined at 128 that a packet is to be read, the first segment (A1) from bank A is read while preparing bank B at 130. The second segment (Bi) is fetched from bank B while preparing bank A at 132. Because the length of the packet is not necessarily known when fetching a packet, it may occur that the segment fetched from bank A is the end of packet. This cannot be readily determined, due to latency, until the segment (Bi) is fetched at 132. Thus, it is determined at 134 whether the previously fetched segment (Ai) is the end of packet. If it is the end of packet, the just fetched (Bi) segment is discarded and the read cycle is terminated at 136. If the first fetched (Ai) segment was not the end of packet, the next segment from the A bank is fetched while preparing the B bank at 138. It is then determined at 140 whether the segment (Bi) which was fetched at 132 is the end of the packet. If it is, the segment fetched from the A bank at 138 is discarded and the read cycle ended at 142. Otherwise, the B bank is accessed again at 132 and the process continues until the end of packet segment is found.

Although the invention can be used with SDRAM having more than two banks, it is not necessary to use more than two banks when storing any single packet.

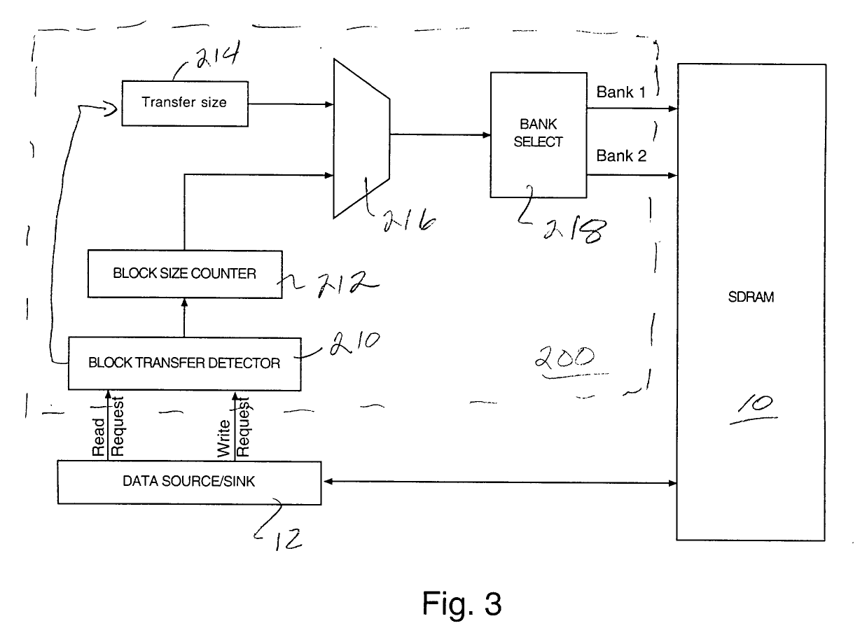

FIG. 3 is a high level block diagram of an apparatus 200 for performing the methods of the invention in conjunction with SDRAM 10 and a source/sink of data 12. The apparatus 200 generally includes a block transfer detector 210, a block size counter 212, a transfer (segment) size indicator 214, a comparator 216, and a bank selector 218. When a data source or sink 12 initiates a data transfer between it and SDRAM 10, the block transfer detector 210 determines the nature of the transfer, e.g. the size of the packet, the number of segments, etc. and passes this information to the transfer size indicator 214 and block size counter 212. As blocks are transferred to/from the RAM 10, the block size counter 212 updates the block count which is compared by comparator 216 with the transfer block size stored in the transfer size indicator 214. Once the number of blocks in a segment is reached, the bank selector switches banks.

As described in the attached appendix, the presently preferred embodiment of the invention is designed to operate with the PC133 SDRAM specification. Signals between the apparatus 200 and external SDRAM 10 include all the necessary signals and timing required by external PC133 SDRAM to accomplish read or write data transfers. Detailed operation of the signals is contained in the PC133 SDRAM Specification Revision 1.7, Intel Corporation, November 1999, available at URL: http://developer.intel.com/technology/memory/pc133sdram/spec/sdram133.htm. All transfers are synchronous to the clock (RAMCLK).

The apparatus 200 is preferably implemented with the WISHBONE System-On-Chip Interconnection Architecture for Portable IP Cores (Wishbone), Revision B.1 (preliminary) Jan. 8, 2001, Silicore Corporation, Corcoran, Minn. (www.silicore.net).

The apparatus 200 operates as a memory controller and provides support for multiple clients. Data transfers to or from the apparatus 200 are initiated by any one or all of the memory clients. These transfers conform to the Wishbone Block Read or Block Write cycles. The apparatus includes arbitration logic to allow resolution of multiple requests from clients. The arbitration logic prioritizes the client requests and selects the next client to be granted access.

There have been described and illustrated herein several embodiments of method and apparatus for enhancing the efficiency of dynamic RAM. While particular embodiments of the invention have been described, it is not intended that the invention be limited thereto, as it is intended that the invention be as broad in scope as the art will allow and that the specification be read likewise. Thus, while particular method steps have been disclosed in a certain order, it will be appreciated that it may be possible to perform some steps in a different order. Also, while particular SDRAM has been disclosed, it will be recognized that other types of SDRAM could be used with similar results obtained. It will therefore be appreciated by those skilled in the art that yet other modifications could be made to the provided invention without deviating from its spirit and scope as so claimed.

1. A method for enhancing the efficiency of SDRAM during block transfer, comprising:
a) dividing each data block into at least two parts;
b) reading/writing the first part in one bank of the SDRAM; and
c) reading/writing the second part in a different bank of the SDRAM.

2. The method according to claim 1, wherein:
the first part of the data block is a first plurality of words and the second part of the data block is a second plurality of words.

3. The method according to claim 2, wherein:
said first plurality of words is six words and said second plurality of words is eight words.

4. The method according to claim 3, wherein:
each data block contains an ATM cell.

5. The method according to claim 1, wherein:
each data block is a communications packet, and
the number of parts each data block is divided into depends on the size of the packet.

6. The method according to claim 1, wherein:
the SDRAM has a burst length (BL) of x words,
the data block has a block size (BS) of y words,
the first part of the data block is BS-BL words and the second part of the data block is BL words.

7. The method according to claim 1, wherein:
said step of dividing each data block into at least two parts includes dividing each data block into n parts where n>2,
said steps of reading/writing are performed on alternating banks for each of the n parts.

8. An apparatus for enhancing the efficiency of SDRAM during block transfer, comprising:
a) means for dividing each data block into at least two parts; and
b) means for selecting between at least two banks of SDRAM during block transfer, whereby
the first part of the block is read/written in one bank of the SDRAM; and
the second part of the block is read/written in a different bank of the SDRAM.

9. The apparatus according to claim 8, wherein:
the first part of the data block is a first plurality of words and the second part of the data block is a second plurality of words.

10. The apparatus according to claim 9, wherein:
said first plurality of words is six words and said second plurality of words is eight words.

11. The apparatus according to claim 10, wherein:
each data block contains an ATM cell.

12. The apparatus according to claim 8, wherein:
each data block is a communications packet, and
the number of parts each data block is divided into depends on the size of the packet.

13. The apparatus according to claim 8, wherein:
the SDRAM has a burst length (BL) of x words,
the data block has a block size (BS) of y words,
the first part of the data block is BS-BL words and the second part of the data block is BL words.

14. The apparatus according to claim 8, wherein:
said means for dividing each data block into at least two parts includes means for dividing into n parts where n>2, and
during block transfer said means for selecting selects alternating banks for each of the n parts.

15. A method for storing telecommunications packets in SDRAM, comprising:
a) dividing each packet into two parts;
b) storing one part in one bank of the SDRAM; and
c) storing the other part in a different bank of the SDRAM.

16. The method according to claim 15, wherein:
at least one of the parts is equal in length to the burst length of the SDRAM.

17. The method according to claim 15, wherein:
each packet is an ATM cell.

18. A method for storing telecommunications packets in SDRAM comprising:
a) dividing each packet into n parts where n is an integer greater than one; and
b) storing consecutive parts in different banks of SDRAM.

19. The method according to claim 18, wherein:
n is variable depending on the length of the packet.

20. The method according to claim 18, wherein:
at least n−1 of the parts are equal in length to the burst length of the SDRAM.
